(19) United States
(12) Patent Application Publication
(10) Pub. No.: US 2017/0070193 A1
(43) Pub. Date: Mar. 9, 2017

(54) RF Power Amplifier with Post-Distortion Linearizer

(71) Applicants: Ying-Zong Juang, HSINCHU CITY (TW); Hann-Huei Tsai, HSINCHU CITY (TW); Po-Chang Wu, HSINCHU CITY (TW); Kuei-Cheng Lin, HSINCHU CITY (TW); Chih-Yuan Yeh, HSINCHU CITY (TW); Hwann-Kaeo Chiou, HSINCHU CITY (TW)

(72) Inventors: Ying-Zong Juang, HSINCHU CITY (TW); Hann-Huei Tsai, HSINCHU CITY (TW); Po-Chang Wu, HSINCHU CITY (TW); Kuei-Cheng Lin, HSINCHU CITY (TW); Chih-Yuan Yeh, HSINCHU CITY (TW); Hwann-Kaeo Chiou, HSINCHU CITY (TW)

(73) Assignee: NATIONAL APPLIED RESEARCH LABORATORIES, HSINCHU CITY (TW)

(21) Appl. No.: 14/948,380

(22) Filed: Nov. 22, 2015

(30) Foreign Application Priority Data
Sep. 9, 2015 (TW) 104129728

(51) Int. Cl. H03F 1/02; H03F 3/193; H03F 3/21; H03F 1/32

(52) U.S. Cl. CPC H03F 1/0211; H03F 1/3205; H03F 3/193; H03F 3/211; H03F 2200/451; H03F 2203/21106; H03F 2201/3215

(57) ABSTRACT

The invention provides an RF power amplifier with post-distortion linearizer. The power amplifier includes a main amplifier, an auxiliary amplifier and a phase compensator. The first amplifier has a first input end and a first output end and operates in class A or AB. The auxiliary amplifier has a second input end and a second output end and operates in class B or C. The second output end connects the first output end to form a signal output end. The phase compensator has a third input end and a third output end and compensates a phase difference between the main and auxiliary amplifiers to make outputs of the two amplifiers opposite in phase. The third output end connects the second input end. The third input end connects the first input end to form a signal input end.

### BACKGROUND OF THE INVENTION

1. Technical Field

The invention relates to amplifiers, particularly to radio frequency power amplifiers.

2. Related Art

Cell phones have been necessary for modern people. Popularization of smartphones further promotes application and development of more various peripherals, for example, various wireless peripherals based upon industrial standards such as the Wi-Fi, BLUETOOTH and MIRACAST. With the extensive application of wireless devices, a radio frequency (RF) power amplifier required by wireless devices has to progress continuously to satisfy various requirements.

Because an RF power amplifier must be installed in mobile devices such as cell phones, tablets and wireless headphones, its design has to consider many factors, such as power, linearity, gain, efficiency, cost, volume, weight, etc., to accomplish an object of optimization. However, currently available RF power amplifiers cannot make a better balance among the abovementioned factors, for example, U.S. Pat. No. 7,821,337, US patent application Nos. 2011/0050345 and 2007/0222512. Therefore, an RF power amplifier with high efficiency, high performance and simple structure is urgently required by the industry.

### SUMMARY OF THE INVENTION

A primary object of the invention is to provide an RF power amplifier with post-distortion linearizer, which utilizes simple circuitry to obtain extremely high linearity and power added efficiency (PAE).

Another object of the invention is to provide an RF power amplifier with post-distortion linearizer, which can be completely integrated on a single chip to obtain effects of lightweight, compactness and cost-down.

To accomplish the above object, the RF power amplifier with post-distortion linearizer of the invention includes a main amplifier, an auxiliary amplifier and a phase compensator. The first amplifier has a first input end and a first output end and operates in class A or AB. The auxiliary amplifier has a second input end and a second output end and operates in class B or C. The second output end connects the first output end to form a signal output end. The phase compensator has a third input end and a third output end and compensates a phase difference between the main and auxiliary amplifiers to make outputs of the two amplifiers opposite in phase. The third output end connects the second input end. The third input end connects the first input end to form a signal input end.

### BRIEF DESCRIPTION OF THE DRAWINGS

FIG. 1 is a block diagram of the invention;

FIGS. 2A, 2B and 2C are circuit character diagrams of the invention; and

FIG. 3 is a circuit diagram of a preferred embodiment of the invention.

### DETAILED DESCRIPTION OF THE INVENTION

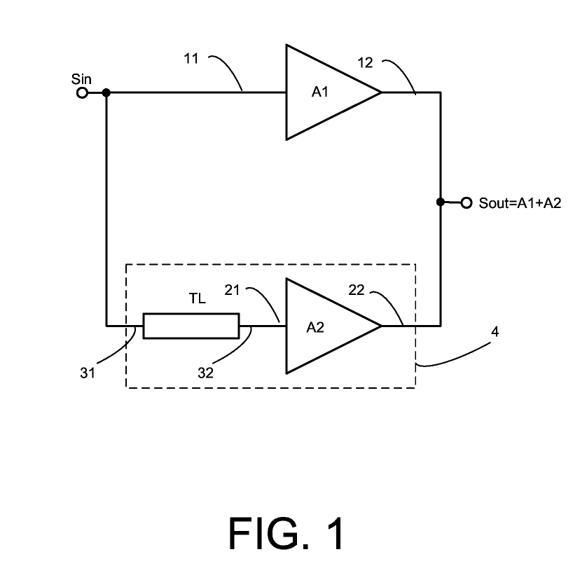

Please refer to FIG. 1. The invention provides an RF (radio frequency) power amplifier with post-distortion linearizer, which primarily includes a main amplifier A1, an auxiliary amplifier A2 and a phase compensator TL. By means of selecting a ratio of transistor sizes of the two amplifiers A1 and A2, DC bias points and adjusting output phase through the phase compensator TL, the output power and linearity of the power amplifier can be enhanced. The auxiliary amplifier A2 is equivalent to load modulation. It compensates the output characters of the main amplifier A1 to improve 1-dB compression point power (OP_{1dB}). When starting the post-distortion linearizer 4, the third-order distortion of the main amplifier A1 can be eliminated at the output end so as to make the 1-dB compression point power (OP_{1dB}) approach a saturated output power. And the linear output power and power added efficiency (PAE) can be increased in the power region of OP_{1dB}.

The main amplifier A1 operates in class A or AB and has a first input end 11 and a first output end 12. The main amplifier A1 is used to provide high gain and output power and possesses great PAE.

The auxiliary amplifier A2 operates in class B or C and has a second input end 21 and a second output 22. The second output end 22 connects the first output end 12 to form a signal output end Sout.

The phase compensator TL has a third input end 31 and a third output end 32. The third output end 32 connects the second input end 21. The third input end 31 connects the first input end 11 to form a signal input end Sin for compensating a phase difference between the main amplifier A1 and the auxiliary amplifier A2 to make outputs of the two amplifiers A1 and A2 opposite in phase. The auxiliary amplifier A2 and the phase compensator TL constitute the post-distortion linearizer 4.

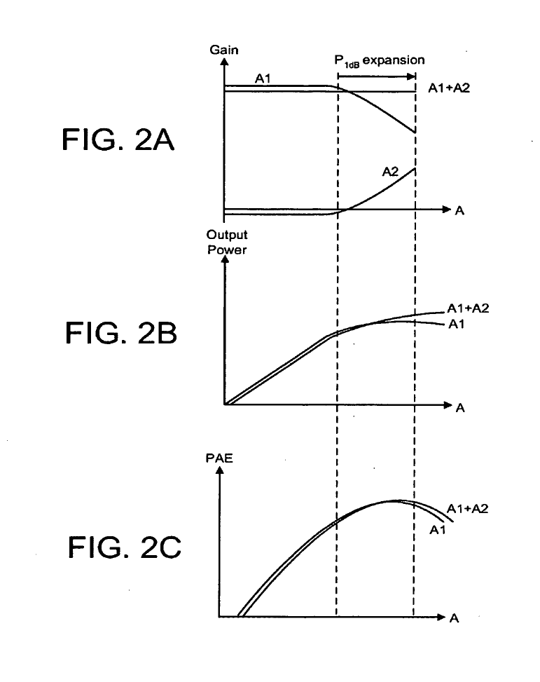

The auxiliary amplifier A2 properly compensates the third-order distortion coefficient in a range near the OP_{1dB} to enhance linearity. When the auxiliary A2 is shut down, the gain primarily comes from the main amplifier A1 as shown in FIG. 2A. The gain is based upon power series analysis and simulation of nonlinear signal. The gain can be expressed by the following formula (1):

$$Gain = \frac{{RF}_{out}}{{RF}_{in}} = \frac{( {a}_{1} A + \frac{3 {a}_{3} {A}^{3}}{4} ) cos ω t}{A cos ω t} = {a}_{1} + \frac{3 {a}_{3} {A}^{2}}{4} \qquad ( 1 )$$

α₁ and α₃ represent the fundamental and third-order distortion coefficients of the PA, and A and ω represent the input voltage magnitude and operation frequency, respectively.

Please refer to FIGS. 2A, 2B and 2C, which show character diagrams of gains, output powers and PAEs (power added efficiency) with respect to input voltage magnitude A of the main and auxiliary amplifiers A1 and A2. As shown in FIG. 2A, the gain at high input voltage will reduce due to the nonlinear third-order distortion. When the auxiliary amplifier A2 becomes conductive, the signal Sin is introduced to the main and auxiliary amplifiers A1 and A2. The phase compensator TL before the auxiliary A2 is used for adjusting the phase output of the auxiliary amplifier A2 to make the auxiliary amplifier A2 obtain a third-order distortion coefficient which is opposite to the main amplifier A1 in phase. By means of selecting a ratio of transistor sizes of the two amplifiers A1 and A2 and DC bias points, the third-order distortion coefficients of the main and auxiliary amplifiers A1, A2 will have a character of the same values and phase contrast. Because the output ends 12, 22 of the main and auxiliary amplifiers are connected together, the third-order distortion coefficients of the main and auxiliary amplifiers A1, A2 will be offset. Formula (1) can be expressed by formula (2):

$$Gain = ( {a}_{1 , A 1} + \frac{3 {a}_{3 , A 1} {A}^{2}}{4} ) + ( {a}_{1 , A 2} + \frac{3 {a}_{3 , A 2} {A}^{2}}{4} ) {a}_{1 , A 1} + {a}_{1 , A 2} \qquad ( 2 )$$

Where α_{1,A1} and α_{1,A2} stand for the fundamental coefficients of the main and auxiliary amplifiers A1, A2, respectively. And α_{3,A1} and α_{3,A2} stand for the third-order distortion coefficients of the main and auxiliary amplifiers A1, A2, respectively.

Under the design of the invention, the third-order distortion can be eliminated near the output node OP_{1dB} to obtain an effect of only A1 coefficient existing, then a linear gain can be obtained. Because the auxiliary amplifier A2 is set to operate in class B or C, its gain is attenuated. By the size ratio of the main and auxiliary amplifiers A1, A2, α_{1,A1} is much greater than α_{1,A2}. Thus formula (2) can be simplified as follows:

Gain≈α_{1,A1}

The auxiliary amplifier A2 can compensate the third-order distortion coefficient near OP_{1dB} power, but the gain will be slightly reduced within a low input power range. The power amplifier of the invention implements a character of high linearity. The linear output power and PAE operating range can be increased within power range of OP_{1dB}.

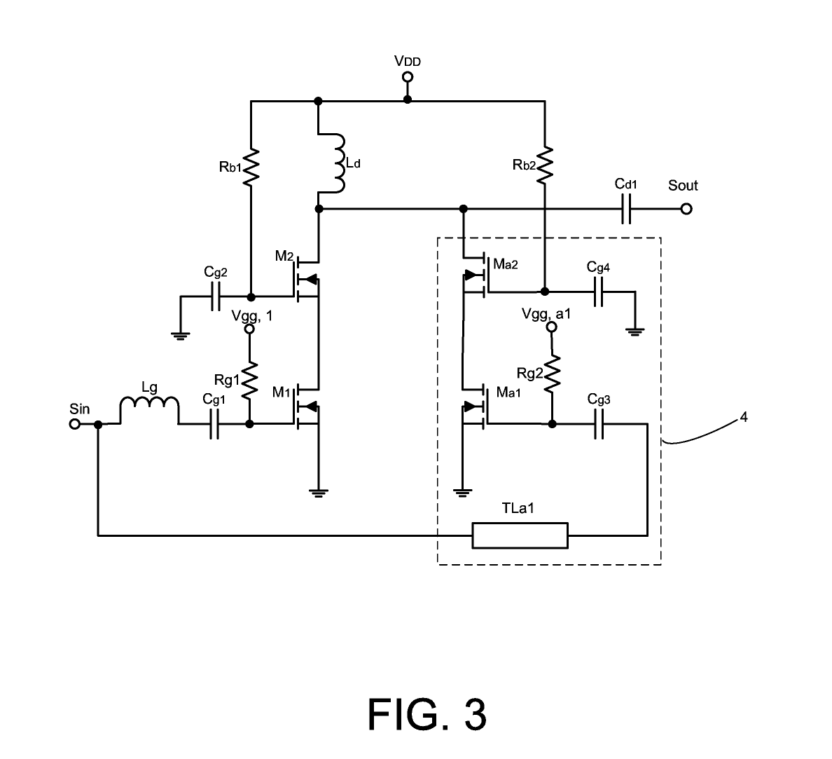

The invention may be a one-stage or multi-stage power amplifier. FIG. 3 shows a preferred embodiment of a one-stage power amplifier with post-distortion linearizer, where the operating frequency is 5 GHz. Its measured results are: when the post-distortion linearizer 4 is not started, the linear output power of the amplifier is 17.7 dBm, which has a difference of 2.3 dB against the saturated output power, and the efficiency is 29.7%; when the post-distortion linearizer 4 is started, the linear output power of the amplifier is 20 dBm, which has a difference of mere 0.2 dB against the saturated output power, and the efficiency is increased by 2.9%. These results express that the post-distortion linearizer 4 can effectively increase the linear operating dynamic range of power amplifier.

It will be appreciated by persons skilled in the art that the above embodiment has been described by way of example only and not in any limitative sense, and that various alterations and modifications are possible without departure from the scope of the invention as defined by the appended claims.

What is claimed is:

1. An RF (radio frequency) power amplifier with post-distortion linearizer, comprising:
a main amplifier, having a first input end and a first output end;
an auxiliary amplifier, having a second input end and a second output end, wherein the second output end connects the first output end to form a signal output end; and
a phase compensator, having a third input end and a third output end, wherein the third output end connects the second input end, the third input end connects the first input end to form a signal input end for compensating a phase difference between the main amplifier and the auxiliary amplifier to make outputs of the two amplifiers opposite in phase.

2. The RF power amplifier of claim 1, wherein the main amplifier operates in class A.

3. The RF power amplifier of claim 1, wherein the main amplifier operates in class AB.

4. The RF power amplifier of claim 1, wherein the auxiliary amplifier operates in class B.

5. The RF power amplifier of claim 1, wherein the auxiliary amplifier operates in class C.
